(19) United States
(12) Patent Application Publication
(10) Pub. No.: US 2025/0279628 A1
(43) Pub. Date: Sep. 4, 2025

(54) Tunable laser with tilt tuned interference filter with blocking filter

(71) Applicant: KineoLabs, Inc., Billerica, MA (US)

(72) Inventor: Walid A. Atia, Jamaica Plain, MA (US)

(21) Appl. No.: 19/070,027

(22) Filed: Mar. 4, 2025

Related U.S. Application Data
(60) Provisional application No. 63/561,030, filed on Mar. 4, 2024.

(51) Int. Cl. H01S 5/14; H01S 5/00; H01S 5/026

(52) U.S. Cl. CPC H01S 5/141; H01S 5/0078; H01S 5/0267

(57) ABSTRACT

A tunable laser, specifically a cat's eye tunable laser, includes a blocking filter along with the interference filter, which is manipulated for laser tunability. The blocking filter ensures single order operation and enhances the overall performance of the laser by addressing common issues such as multi-order lasing, unstable laser output, and loss across the tuning band.

### RELATED APPLICATIONS

This application claims the benefit under 35 USC 119 (e) of U.S. Provisional Application No. 63/561,030, filed on Mar. 4, 2024, which is incorporated herein by reference in its entirety.

### BACKGROUND OF THE INVENTION

Tunable lasers have become an essential tool in various fields of research and industry, including telecommunications, medical imaging, and environmental sensing, among others. In particular, the cat's eye configuration has gained popularity due to its high performance and stability. This setup typically includes a gain chip, a collimating lens, a bandpass interference filter, and a cat's eye mirror/output coupler, defining a laser cavity where laser amplification occurs.

The tunability of the laser is often achieved by manipulating the bandpass interference filter in the beam path. The most common method is tilt tuning, which involves changing the angle of the filter with respect to the collimated beam. This changes the passband of the filter, allowing the laser to scan or sweep over a range of wavelengths.

### SUMMARY OF THE INVENTION

However, conventional cat's eye tunable lasers have their limitations. One major issue is the risk of multi-order lasing, where the laser can lase at multiple transmission peaks of the bandpass interference filter. This can lead to undesirable effects such as unstable or undesired laser output. Furthermore, the performance of the laser can be affected by the divergence of the beam, the polarization of the light, and the loss across the tuning band.

In light of these challenges, there is a need for improvements in the design of cat's eye tunable lasers. This invention aims to address these issues by introducing a blocking filter into the laser's cavity, thus ensuring single order operation and enhancing the overall performance of the laser.

The invention provides an enhanced design for a tunable laser, such as a cat's eye tunable laser. The laser's cavity includes a blocking filter, ensuring single order operation and improving the overall performance of the laser. The blocking filter can be integrated with the interference filter, which is manipulated for laser tunability, such as tilt tuning. This design addresses common issues such as multi-order lasing, unstable laser output, and loss across the tuning band. The disclosure also presents specifications for the beam size, polarization, and tuning speed, and details on how the beam is collimated and transmitted.

At its core, the system features a semiconductor gain chip—preferably a single angled facet (SAF) chip with a high-reflectivity rear facet and an anti-reflective angled front facet (e.g., to suppress parasitic reflections and to enhance tuning smoothness)—positioned to emit light that is collected and collimated by a collimation lens. The collimated beam then passes through a bandpass interference filter having multiple transmission peaks or passbands spaced by a free spectral range, where a blocking filter (such as a multi-layer dielectric long-pass coating) is integrated in the same substrate or in close operative association with a bandpass filter. In one embodiment, the blocking filter is implemented as a multi-layer dielectric coating configured as a long-pass or short-pass filter that shifts in cutoff wavelength when tilted or otherwise moves with respect to the collimated beam.

Because typical bandpass interference filters inherently exhibit multiple orders of transmission that can overlap the gain bandwidth, this invention places the blocking filter within the laser cavity to prevent undesired higher-order passbands from aligning with the gain spectrum of the chip. By ensuring that only a single passband of the bandpass filter falls within the semiconductor gain bandwidth and sees gain in the laser cavity at any tilt angle, the blocking filter effectively suppresses multi-order lasing, stabilizes output power, and reduces mode competition. The blocking filter may be formed on the same substrate as the bandpass filter. In one embodiment, both the bandpass filter and the blocking filter reside on opposing surfaces of a common transparent substrate to form the bandpass interference filter, allowing the cutoff edge of the blocking filter to track and shift in unison with the main passband of the passband filter as it is tilt-tuned. In one embodiment, the blocking filter substantially blocks lasing on higher-order transmission peaks of the bandpass filter so that only a single bandpass filter passband sees gain in the cavity at any given tilt angle. In one embodiment, the bandpass filter has a full-width-half-maximum (FWHM) passband of less than 5 nanometers, and the blocking filter ensures that, for any tilt angle within an operational sweep range, no more than one transmission peak of the interference filter overlaps with the gain bandwidth during operation.

The laser cavity is typically completed by a mirror that defines one end of the cavity opposite the gain chip's reflective facet. In certain embodiments, the mirror comprises a partial reflector in a cat's eye arrangement, i.e., using a focusing lens and a reflective surface (an output coupler or cat's eye mirror) at the lens's focal plane, thereby providing stable, low-loss operation. The system can be swept or tuned by tilting the bandpass interference filter-often via a galvanometer or rotational actuator-causing its center wavelength to scan across at least 50 nanometers of the chip's gain bandwidth while maintaining single-order lasing. In one embodiment, the galvanometer or rotational actuator is coupled to the bandpass interference filter so as to tilt the bandpass interference filter with respect to the collimated beam, thereby sweeping the passband over at least 50 nanometers of the gain bandwidth.

Additionally, a method of operating the tunable laser is disclosed. The method includes: (1) collimating light from the semiconductor gain chip, (2) placing a bandpass interference filter in the collimated beam to define a wavelength-selective passband, (3) incorporating a blocking filter in operative association with the bandpass interference filter to suppress multi-order lasing and/or undesired transmission peaks (e.g., by blocking at least one undesired passband of the bandpass interference filter from overlapping with the gain bandwidth of the semiconductor gain chip and seeing gain), (4) reflecting a portion of the filtered beam back into the gain chip to form the laser cavity, and (5) adjusting the bandpass interference filter (e.g., tilt-tuning) over a desired wavelength range (e.g., adjusting the bandpass interference filter to sweep the laser output wavelength across a desired tuning range). By continuously monitoring the output beam—potentially with photodetectors—it is confirmed that the blocking filter preserves single-order lasing, thus eliminating output instabilities or multi-order interference effects.

In sum, this invention addresses key challenges in external-cavity tunable lasers by integrating a blocking filter with a bandpass filter and possibility into the same interference filter, ensuring that only a single interference peak overlaps the semiconductor gain at any given time. It further leverages cat's eye or standard resonator geometries, SAF chip technology, and tilt-actuated tuning to provide a robust, broadly tunable, single-order laser source suitable for spectroscopy, optical coherence tomography, and other applications requiring stable, narrow-line tunability.

The above and other features of the invention including various novel details of construction and combinations of parts, and other advantages, will now be more particularly described with reference to the accompanying drawings and pointed out in the claims. It will be understood that the particular method and device embodying the invention are shown by way of illustration and not as a limitation of the invention. The principles and features of this invention may be employed in various and numerous embodiments without departing from the scope of the invention.

### BRIEF DESCRIPTION OF THE DRAWINGS

In the accompanying drawings, reference characters refer to the same parts throughout the different views. The drawings are not necessarily to scale; emphasis has instead been placed upon illustrating the principles of the invention. Of the drawings:

FIG. 1 is a perspective view of a tunable laser implemented in a spectroscopy system for example;

FIG. 2 is a side plan schematic cross-sectional view of a butterfly package collimator assembly of the tunable laser;

FIG. 3 is a side plan schematic view of the interference filter according to the present invention; and

FIG. 4 is a plot of power density and transmission of the interference filter.

### DETAILED DESCRIPTION OF THE PREFERRED EMBODIMENTS

The invention now will be described more fully hereinafter with reference to the accompanying drawings, in which illustrative embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

As used herein, the term “and/or” includes any and all combinations of one or more of the associated listed items. Also, all conjunctions used are to be understood in the most inclusive sense possible. Thus, the word “or” should be understood as having the definition of a logical “or” rather than that of a logical “exclusive or” unless the context clearly necessitates otherwise. Further, the singular forms and the articles “a”, “an” and “the” are intended to include the plural forms as well, unless expressly stated otherwise. It will be further understood that the terms: includes, comprises, including and/or comprising, when used in this specification, specify the presence of stated features, integers, steps, operations, elements, and/or components, but do not preclude the presence or addition of one or more other features, integers, steps, operations, elements, components, and/or groups thereof. Further, it will be understood that when an element, including component or subsystem, is referred to and/or shown as being connected or coupled to another element, it can be directly connected or coupled to the other element or intervening elements may be present.

It will be understood that although terms such as “first” and “second” are used herein to describe various elements, these elements should not be limited by these terms. These terms are only used to distinguish one element from another element. Thus, an element discussed below could be termed a second element, and similarly, a second element may be termed a first element without departing from the teachings of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

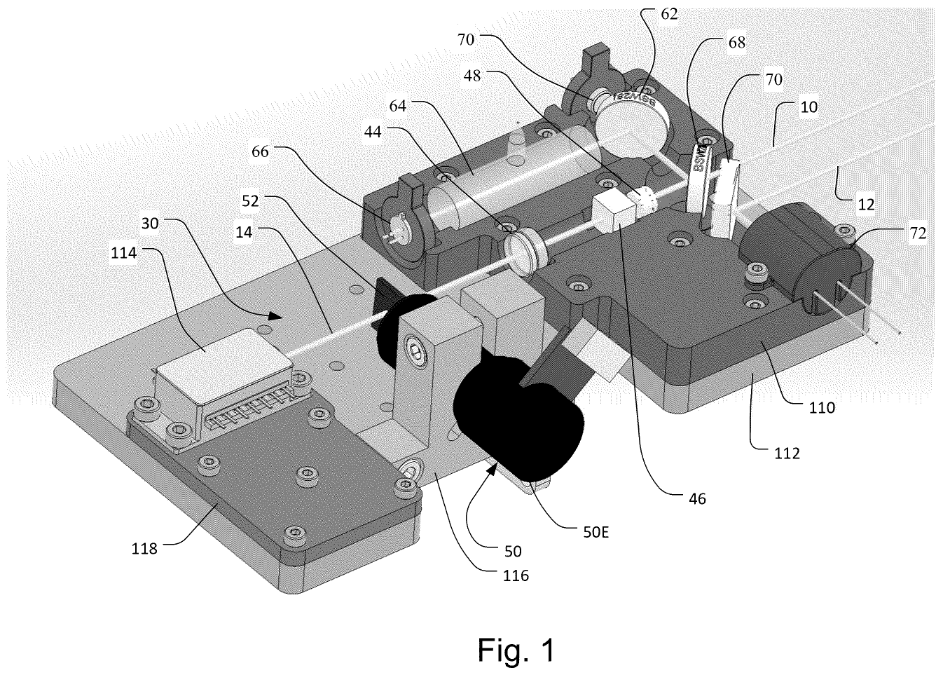

FIG. 1 shows a tunable laser 30 implemented in a spectroscopy system including several detectors for monitoring.

In more detail, mounted on a base bench 112 is a package pedestal 118 and an optical upper bench 110. The benches and pedestal are often 3D printed using a filament-fed, FDM 3D printer or a MSLA (Masked Stereolithography) resin 3D printers. In other examples these benches and pedestal are fabricated from metal such as machined aluminum. A galvanometer clamp 116 secures a galvanometer 50 to the optical base bench 112.

In one example, the base bench 112, pedestal 118, upper bench 110, and galvanometer clamp 116 are constructed from a unitary piece of machined aluminum with an anodized surface finish.

A butterfly package collimator assembly 114 is mounted to the package pedestal 118 and contains a collimation and optical gain assembly. The laser's amplification is provided by an InP gain chip in the illustrated butterfly windowed package or other hermetic enclosure. This package protects the chip from dust and the ambient environment including moisture. In some examples, the butterfly package collimator assembly 114 has an integrated or a separate thermoelectric cooler. In the current example, a lens is also installed in the butterfly package collimator assembly 114 to collimate the light emission from the gain chip to yield the collimation and optical gain assembly.

Other material systems can be selected for the gain chip, however. Common material systems are based on III-V semiconductor materials, including binary materials, such as GaN, GaAs, GaSb, InAs, as well as ternary, quaternary, and pentenary alloys, such as InGaN, InAlGaN, InGaP, AlGaAs, InGaAs, GaInNAs, GaInNAsSb, AlInGaAs, InGaAsP, AlGaAsSb, AlGaInAsSb, AlAsSb, InGaSb, InAsSb, and InGaAsSb. Collectively, these material systems support operating wavelengths from about 400 nanometers (nm) to 2500 nm, including longer wavelength ranges extending into multiple micrometer wavelengths. Semiconductor quantum well, quantum cascade and quantum dot gain regions are typically used to obtain especially wide gain and spectral emission bandwidths, and support operation up to 250 μm in wavelength. Quantum well layers may be purposely strained or unstrained depending on the exact materials and the desired wavelength coverage.

Also other collimator assemblies can be used such as assemblies based on TO-can packages.

In addition, while the invention is being described in the context of a spectroscopy system, the tunable laser 30 can be applied to many other applications such as tunable lasers for swept source optical coherence tomography, to list one other example.

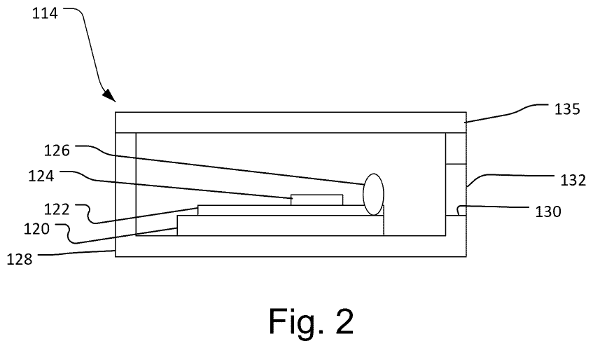

FIG. 2 shows one example of the butterfly package collimator assembly 114 according to the specific illustrated example. A gain chip 124 amplifies light in the wavelength range of about 1500-1800 nm, according to this example. The gain chip 124 may be a semiconductor gain chip, in one example. The preferred chip architecture is termed a single angled facet (SAF) edge-emitting chip. As such, it has a high reflectivity (HR) coated rear facet. It has an antireflective (AR) coated front facet. In addition, for improved performance, it has a curved ridge waveguide that is perpendicular to the rear facet but is angled at the interface with the front facet. This angling at the front facet along with the AR coating reduces reflections at the front facet reflectivity by up to 40 dB and significantly improves laser performance by reducing parasitic reflections that can otherwise lead to non-smooth tuning and mode-hopping.

Preferably its center wavelength is around 1700 nm and tunes in a band of +/−50 nm or more around 1700 nm, or more preferably tunes in a band of +/−100 nm or more around 1700 nm.

The light from the chip 124 is collimated by a lens 126 to form beam 14 that exits the package 128 via a port 130 formed in a sidewall of the package 128. A window 132 is installed in the port 130, with the window preferably having an antireflection coating for the wavelengths of the laser's operation. A lid 135 is welded or otherwise bonded to the package 128 to seal it.

The chip 124 is soldered or silver epoxy bonded to a chip bench 122 that also holds the lens 126. A thermoelectric cooler 120 couples the bench 122 to an inner floor of the package 128.

Returning to FIG. 1, the free space collimated beam 14 emitted through a front optical window of the butterfly package collimator assembly 114 is received by a cat's eye focusing lens 44, which focuses the light onto a cat's eye mirror/output coupler 46. This defines the other end of the laser cavity, extending between the mirror/output coupler 46 and the back/reflective facet of the gain chip 124 in the butterfly package collimator assembly 114. Note that in most embodiments, optical cavity length is between 10 millimeters (mm) and 150 mm in length.

The collimated light between the collimating lens and the cat's eye focusing lens 44 passes through a bandpass interference filter 52 that is angle tuned in the beam by a tilt actuator such as a galvanometer 50.

The general design parameters yield a large number of longitudinal modes under the envelope for the filter linewidth for a laser cavity length of 50 millimeters (mm). In the preferred embodiment, there are at least 15 modes under the filter envelope and at least 5 lasing modes for linewidth narrowed emission to 0.5 nm. Ideally, there are at least 25 modes and possibly 37 modes or more and at least 7 modes to 10 or more modes for linewidth narrowed emission.

This large number of modes works well for low noise spectral analysis. And keep in mind that the larger the number of modes, the lower the modal noise (by sqrt (number of modes)). However, the amplitude referencing takes out amplitude noise through common mode noise rejection either by digital division or constant power control while sweeping over the tuning range.

The bandpass interference filter 52 is held on an arm of tilt actuator or galvanometer 50 in the current example. This allows for tilting of the bandpass interference filter in the collimated beam to thereby tilt tune the filter and thus change the passband to scan or sweep the wavelength of the swept laser 100.

In the illustrated example, the tilt actuator is a servo galvanometer and includes an integrated encoder 50E. In other examples, the angle control actuator 50 is a servomotor or an electrical motor that continuously spins the bandpass interference filter 52 in the collimated beam 14. This allows for tilting of the bandpass interference filter 52 with respect to the collimated beam 14 to thereby tilt-tune the filter and thus change the passband to scan or sweep the wavelength of the swept laser.

Tuning speed specifications for the galvanometer 50 generally range from 0.1 Hz to 50 kHz. For the higher speeds, a 25 kHz resonant galvo can be used with bi-directional tuning, but higher and lower speeds can be used. Wavelength tuning speed is usually given in nm/sec. In general, the tuning speed should be between 3000 nm/sec and 11000 nm/sec.

The size of the collimated beam is important for many applications. As a general rule, a smaller beam results in higher divergence resulting in a larger cone half angle (CHA), which is the divergence of the beam hitting the tunable filter. This reduces the minimum line width over angle for a tunable filter. In the current embodiment, the CHA must be smaller than a given amount, typically 0.025 degrees, in order to maintain both linewidth and loss.

Note that a higher divergence beam has a smaller diameter, so this means collimated beams of a large enough diameter are required to provide the required maximum CHA, and larger beams require physically larger tunable filters. A beam size of ˜1 millimeters (mm) is typical for a CHA of 0.025 degrees, but because the beam from the chip is elliptical this should be chosen to be the smaller axis beam. Moreover, we can then choose the final output collimating lens that forms a telescope from the cat's eye focusing lens to have an output beam of whatever desired diameter we would like, with the magnification given by the ratio of the output lens focal length to the focusing lens focal length. Note that if desired the elliptical output beam is circularized with the use of anamorphic prism pairs, a pair of cylindrical lenses, or a simple spatial filter at the output, in different examples.

In any event, the beam size of beam 14 for the small axis at the tunable filter 52 is preferably between 0.5 and 2 mm.

The light from the gain chip is polarized. In the common architectures, the polarization is horizontal or parallel to the epitaxial layers of the edge-emitting gain chip. In the preferred configuration, the filter is oriented to receive the S polarization in order to maintain narrow line width of the filter as it is tilt tuned. On the other hand, the P polarization broadens drastically at large tilt angles. S polarization has higher loss at larger tilt angles than P. So, the filter design needs to address these issues by providing a low enough loss across the tuning band for S.

In general, the present cat's-eye configuration provides a number of advantages. It provides low loss, low tolerance, repeatable stable operation since lower angle wavelength change over grating-based lasers.

The mirror/output coupler 46 will typically reflect less than 90% and preferably about 80% of the light back into the laser's cavity and transmits greater than 10% and preferably about 20% of light. Often, the transmitted light is collimated with the help of an output collimating lens 48. More generally, the mirror/output coupler can reflect from 10% to 99% of light (transmitting 90% to 1%, respectively), depending on the output power and laser cavity loss desired. Higher reflectivity results in lower loss cavities and thus wider laser tuning range where gain exceeds loss, but results in lower output power.

In some embodiments, an iris or mask is added typically after the output coupler to clip the beam edge. This reduces power fluctuations as the beam wanders due to refraction in the tilting bandpass interference filter.

In the exemplary system shown in FIG. 1, the portion of the beam passing through the output coupler 46 is collimated by output collimating lens 48 and the collimated beam is typically received by output beamsplitter 68 that directs a portion of the beam to a reference beamsplitter 62. This divides the beam, such as a few percent to gas cell 64. After passage through the gas cell, the light is then detected by a gas cell detector 66. The transmitted light at the reference beamsplitter 62 is received by an amplitude reference detector 70.

The gas cell is employed for calibration for the detection of the same or similar gas by the system.

In other embodiments, the gas cell is replaced by a different gas cell. Currently, the system is intended to quantify the concentration of methane, so methane is contained in the gas cell, but other gases or mixtures of gases can be contained in the cell. In still another example, the gas cell is replaced with a stable wavelength reference such as an etalon.

For holding the various components, it has a series of cradles or V-groove optical element mounting locations formed into the top surface of the upper bench 110.

According to the invention, a blocking filter is provided in the laser's cavity.

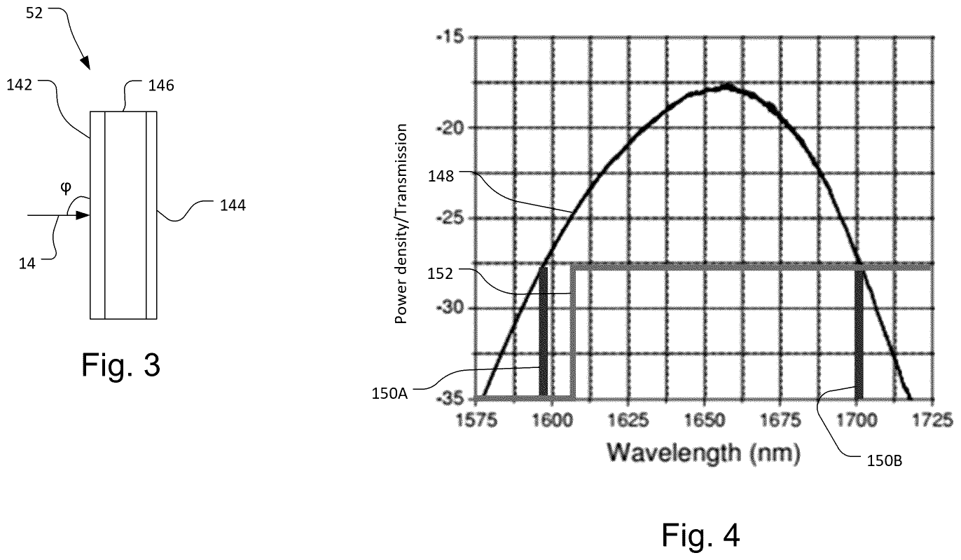

FIG. 3 shows the preferred implementation of the blocking filter, i.e., integrated with a bandpass filter 142 to form the interference filter 52.

In more detail, the interference filter 52 comprises a bulk substrate 146. This is often a glass or other silicon based material.

A single or multi-cavity bandpass filter 142 is fabricated on a front surface of the bulk substrate 146. The free spectral range of the bandpass filter 142 is based in part on its thickness. As the angle to the beam 14 changes anyway from orthogonal to the interference filter 52 (shown), the passband of the bandpass filter 142 shifts to shorter wavelengths.

In the present design, the free spectral range of the bandpass filter 142 or spectral distance between the orders of the filter is preferably greater than 200 nm and is preferably over 300 nm such as about 350 nm. This range defines the distance in nanometers between spectral passbands of bandpass filter 142.

The so-called “effective refractive index” of the bandpass filter 142 is preferably greater than 1.50, and is ideally higher than 1.60, such as 1.65.

In one embodiment, the bandpass filter 142 has a full-width-half-maximum (FWHM) passband of less than 5 nanometers. The passband for the bandpass filter 142 is preferably between 1 and 3 nanometers (nm), and more narrowly between 1.5 and 2.5 nm, FWHM. In one design, it is 2 nm. But, in operation, linewidth narrowing (˜4×) reduces the number of modes that instantaneously lase in the laser cavity for the effective laser linewidth.

Yet in other examples requiring less resolution, the passband for the bandpass filter 142 is less than 10 nm and usually less than 5 nm.

A blocking filter 144 is integrated with or disposed in operative association with the bandpass filter 142. In some embodiments, the blocking filter 144 is formed on the same substrate as the bandpass filter 142 to form a unitary interference filter 52. The bandpass filter 142 and the blocking filter 144 are formed on opposing surfaces of a common transparent substrate, such as the bulk substrate 146. In the illustrated example, the blocking filter 144 is fabricated on the back surface of the bulk substrate 146.

The blocking filter 144 is configured to block at least one of the bandpass filter's transmission passbands from overlapping with a gain bandwidth of the gain chip (e.g., in order to ensure single-order lasing). In one example, the blocking filter 144 ensures that, for any tilt angle within an operational sweep range, nor more than one transmission peak of the interference filter 52 overlaps with the gain bandwidth. The blocking filter 144 is designed so that as its angle to the beam 14, the cut-off wavelength of the blocking filter shifts spectral passbands of bandpass filter 142.

In one embodiment, a method of operating the tunable laser 30 comprises collimating light (e.g., via the collimating lens) emitted by the gain chip 124 to form the collimated beam 14; disposing the bandpass interference filter 52 in the collimated beam 14 such that the interference filter 52 defines a passband that can be tuned; providing the blocking filter 144 integrated with or in operative association with bandpass filter 142 of the interference filter 52, the blocking filter 144 being configured to suppress multi-order lasing by blocking at least one undesired passband of the bandpass filter 142 from overlapping with the gain bandwidth of the gain chip 124; reflecting a portion of the filtered beam back into the gain chip 124, thereby forming a laser cavity; and adjusting the bandpass filter 142 (e.g., via the tilt actuator or galvanometer 50) to sweep the laser output wavelength across a desired tuning range while maintaining single-order lasing. The method may further comprise manipulating the bandpass filter 142 (e.g., via tilt tuning, via the tilt actuator or galvanometer 50) to alter its passband and thus the wavelength of the laser system 30.

The blocking filter 144 is constructed from a multi-layer dielectric coating. In some embodiments it is a long-pass filter. The cutoff wavelength shifts with tilting with respect to the collimated beam 14 in the same direction of the shifts in the passband of the bandpass filter 142.

In other examples a short-pass filter is used when the blocking filter is not integrated with the bandpass filter 142.

FIG. 4 is a plot of power density and transmission as function of wavelength. The usable gain band 148 of the chip 124 extends from less than 1600 nm to greater than 1700 nm. The bandpass filter 142 having one, two or more cavities, will have several orders or peaks in transmission 150A, 150B. Within certain angular ranges to the beam 14, multiple peaks in transmission 150A, 150B will fall within the gain band 148 of the chip 124 as shown in the situation where the filter 52 has tilted far away from orthogonal. In the illustrated example near its maximum tilt angle, the laser can lase at either or both of transmission peaks 150A and/or 150B. However, single order lasing is ensured because the transfer function 152 of the blocking filter 144 functions as a long-pass filter, which removes laser cavity gain for transmission peak 150B of the bandpass filter 142. This ensures single order operation of the tunable laser 30.

While this invention has been particularly shown and described with references to preferred embodiments thereof, it will be understood by those skilled in the art that various changes in form and details may be made therein without departing from the scope of the invention encompassed by the appended claims.

What is claimed is:

1. A tunable laser system comprising:
a semiconductor gain chip;
a collimation lens configured to receive and collimate the light emitted from the gain chip;
a focusing lens disposed to receive the collimated beam, and
a mirror positioned defining a laser cavity,
a bandpass filter disposed in the collimated beam path, the bandpass filter having a plurality of transmission passbands spaced apart by a free spectral range; and
a blocking filter integrated with or disposed in operative association with the bandpass filter, the blocking filter being configured to block at least one of the bandpass filter's transmission passbands from overlapping with a gain bandwidth of the semiconductor gain chip in order to ensure single-order lasing.

2. The tunable laser system of claim 1, wherein the blocking filter is formed on the same substrate as the bandpass filter to form a bandpass interference filter.

3. The tunable laser system of claim 1, wherein the blocking filter is a multi-layer dielectric coating being configured as a long-pass or short-pass filter that shifts in cutoff wavelength when tilted with respect to the collimated beam.

4. The tunable laser system of claim 1, wherein the bandpass filter and the blocking filter are formed on opposing surfaces of a common transparent substrate.

5. The tunable laser system of claim 1, further comprising a galvanometer or rotational actuator coupled to the bandpass filter so as to tilt the bandpass filter with respect to the collimated beam, thereby sweeping the passband over at least 50 nanometers of the gain bandwidth.

6. The tunable laser system of claim 1, wherein the blocking filter substantially blocks higher-order transmission peaks of the bandpass filter so that only a single bandpass filter passband lies within the gain bandwidth of the semiconductor gain chip at any given tilt angle.

7. The tunable laser system of claim 1, wherein:
the bandpass filter has a full-width-half-maximum (FWHM) passband of less than 5 nanometers; and
the blocking filter ensures that, for any tilt angle within an operational sweep range, no more than one transmission peak of the bandpass filter overlaps with the gain bandwidth.

8. The tunable laser system of claim 1, wherein the semiconductor gain chip is a single angled facet (SAF) gain chip having a high-reflectivity rear facet and an anti-reflective angled front facet to suppress parasitic reflections and to enhance tuning smoothness.

9. A method of operating a tunable laser that includes a semiconductor gain chip, a resonator, and an interference filter, the method comprising:
collimating light emitted by the semiconductor gain chip to form a collimated beam;
disposing a bandpass filter in the collimated beam such that the bandpass filter defines a passband that can be tuned;
providing a blocking filter integrated with or in operative association with the bandpass filter, the blocking filter being configured to suppress multi-order lasing by blocking at least one undesired passband of the bandpass filter from overlapping with the gain bandwidth of the semiconductor gain chip;
reflecting a portion of the filtered beam back into the gain chip, thereby forming a laser cavity; and
adjusting the bandpass filter to sweep the laser output wavelength across a desired tuning range while maintaining single-order lasing.

10. The method of claim 9, further comprising the step of monitoring the output beam transmitted from the resonator with at least one photodetector, wherein single-order lasing is confirmed.

11. The method of claim 9, wherein the blocking filter is a long-pass or short-pass filter.

12. The method of claim 9, wherein the blocking filter is a multi-layer dielectric coating on the same substrate as the bandpass filter, such that both the bandpass filter and blocking filter tilt in unison with respect to the collimated beam.

13. A tunable laser system, comprising:
a gain chip for amplifying light in a laser cavity;
a collimating lens for forming a collimated beam from the light amplified by the gain chip;
a bandpass interference filter disposed in the path of the collimated beam, the bandpass filter being manipulable to alter its passband and thus the wavelength of the laser system;
a blocking filter disposed within the laser cavity, such that single order lasing operation is ensured; and
an output mirror defining one end of the laser cavity.

14. The tunable laser system of claim 13, wherein the bandpass interference filter is manipulated for tilt tuning.

15. The tunable laser system of claim 13, wherein the blocking filter is specifically designed to address issues of multi-order lasing, unstable laser output, and/or loss across the tuning band.

16. The tunable laser system of claim 13, further comprising a cat's eye focusing lens for focusing the collimated light onto a cat's eye mirror/output coupler.

17. A method of operating the tunable laser system of claim 13, comprising manipulating the bandpass filter to alter its passband and thus the wavelength of the laser system.

18. The method of claim 17, wherein the manipulation of the bandpass interference filter involves tilt tuning.
